(19) United States
(12) Patent Application Publication
(10) Pub. No.: US 2025/0357031 A1
(43) Pub. Date: Nov. 20, 2025

(54) EASY MOUNTABLE WIRELESS DATA COMMUNICATION UNIT AND A SYSTEM COMPRISING IT

(71) Applicant: REMONI A/S, Skanderborg (DK)

(72) Inventor: Bo Eskerod MADSEN, Østbirk (DK)

(21) Appl. No.: 18/869,319

(22) PCT Filed: May 25, 2023
(86) PCT No.: PCT/DK2023/050131

§ 371 Date: Nov. 26, 2024

(30) Foreign Application Priority Data
May 29, 2022 (DK) PA202200493
Mar. 13, 2023 (DK) PA202300224

(51) Int. Cl. H01F 7/02; F21S 8/08; H01F 7/20; H02J 50/30; H04B 7/155

(52) U.S. Cl. CPC H01F 7/0205; F21S 8/085; H01F 7/20; H02J 50/30; H04B 7/15507

(57) ABSTRACT

A wireless data communication unit is provided including a communication module configured to communicate wirelessly, one or more permanent magnets arranged in a manner that enables the unit to be mounted on a magnetizable surface by the one or more permanent magnets is provided. The unit is a self-contained unit formed as a closed housing that is not connected to external power, communication or antenna using cables or wires, wherein the one or more permanent magnets protrude from the housing to such an extent that the one or more permanent magnets can be passivated by of one or more electromagnets arranged and configured to passivate the one or more permanent magnets when the unit is mounted on the magnetizable surface.

### CROSS-REFERENCE TO RELATED APPLICATIONS

This application is a national stage of PCT Application No. PCT/DK2023/050131, having a filing date of May 25, 2023, which is based on DK Application No. PA202300224, having a filing date of Mar. 13, 2023, and DK Application No. PA202200493, having a filing date of May 29, 2022, the entire contents all of which are hereby incorporated by reference.

### FIELD OF TECHNOLOGY

The following relates to a wireless data communication unit comprising a communication module configured to communicate wirelessly and one or more permanent magnets arranged in a manner that enables the unit to be mounted on a magnetizable surface by the one or more permanent magnets, wherein the unit is a self-contained unit formed as a closed housing that is not connected to external power, communication or antenna using cables or wires.

### BACKGROUND

The next generation of measurement and control systems are operated using small wireless sensors and actuators. This development is known as the Internet of Things (IoT).

The many new units enable better control of operation and thereby significant improvements on our environmental and climate impacts.

The IoT solutions have been installed with remarkable success in buildings and production but are still in the very early stages in underground systems. Such systems include grids for power, water, district heating, road surfaces, and city level earthquake monitoring. The reason these types of solutions lack behind is the difficulties of getting reliable internet connectivity for them, as they are mounted underground or very close to the surface of the ground, where internet connectivity is poor.

To circumvent the problem of poor internet connectivity, better coverage is needed. An efficient method to improve connectivity is installation of range extender cells, which add wireless access points to the network which repeat the signals.

The state-of-the-art solution to add range extenders to a network make use of cells which are costly and difficult to install, because they need external supply in form of power, data cables, antenna, and the installer need access to the position where the cell is installed.

US20190207638 A1 discloses a mobile device that is capable of being magnetically attached to a surface. The mobile device comprises a first attachment module, configured to generate a first magnetic field causing the mobile device to be magnetically attached to the surface. The first attachment module, in response to a pick-up signal corresponding to a detected first operation of a user to pick up the mobile device, performs at least one of reducing a strength of the first magnetic field or reversing a polarity of the first magnetic field. This solution, however, requires a rather complex construction. Moreover, electrical energy is required to maintain the generated magnetic field. Accordingly, it would be desirable to have an alternative to this solution.

These limitations are major obstacles to the spread of IoT solutions.

Davis Instruments: “Wireless Repeater with Solar Power”, 29.-07.2021 (URL: https://web.achive.org/web/20210729012458/https://www.da-visinstruments.com/products/wireless-repeater-with-solar-power-3) discloses wireless repeaters designed to be mounted on existing surfaces such as a stationary mast, a light mast, a road sign, a house covering, or a chimney. The wireless repeaters are, however, difficult to mount e.g., by a drone. Accordingly, it would be desirable to provide a solution that eases the mounting procedure.

### SUMMARY

An aspect relates to a wireless data communication unit, by a system, by a kit and a method.

The wireless data communication unit is a wireless data communication unit comprising:
a communication module configured to communicate wirelessly,
one or more permanent magnets arranged in a manner that enables the unit to be mounted on a magnetizable surface by the one or more permanent magnets, wherein the unit is a self-contained unit formed as a closed housing that is not connected to external power, communication or antenna using cables or wires, wherein the one or more permanent magnets protrude from the housing to such an extent that the one or more permanent magnets can be passivated by one or more electromagnets arranged and configured to passivate the one or more permanent magnets when the unit is being mounted on the magnetizable surface.

Hereby, it is possible to attach the unit in an easier way than the conventional art units. By using the one or more electromagnets to passivate the one or more permanent magnets during installation of the unit, the user can move the unit and find the most desirable position without risking that the unit is attached in an undesirable position, from which it cannot be moved. Moreover, when a unit has to be detached or replaced, the unit can easily be moved by using the one or more electromagnets to passivate the one or more permanent magnets during detachment of the unit.

The communication module configured to communicate wirelessly and can be configured to apply any suitable wireless technique. In an embodiment, the communication module configured to communicate wirelessly by using a radio unit.

The one or more permanent magnets may have any suitable shape and size. In an embodiment, the one or more permanent magnets are cylindrical. In an embodiment, the one or more permanent magnets are box shaped. In an embodiment, the one or more permanent magnets are flat (the thickness is less than one fourth of the width).

The one or more permanent magnets are arranged in a manner that enables the unit to be mounted on a magnetizable surface by the one or more permanent magnets. In an embodiment, the one or more permanent magnets protrude from the remaining outer surface of the unit.

The unit is a self-contained unit formed as a closed housing that is not connected to external power, communication or antenna using cables or wires.

The housing may have any suitable shape. In an embodiment, the housing is basically box shaped.

The one or more electromagnets may be part of an instillation device, in which the one or more electromagnets are arranged and configured to passivate the one or more permanent magnets during installation of the unit.

In an embodiment, each electromagnet is shaped in such a manner that each electromagnet can be brought into a position, in which each electromagnet encloses at least a part of one of the permanent magnets.

In an embodiment, the one or more electromagnets are integrated in the unit in such a manner that each of the one or more electromagnets enclose at least a part of one of the permanent magnets.

In an embodiment, each electromagnet totally encloses one permanent magnet.

In an embodiment, each electromagnet totally encloses several permanent magnets.

In an embodiment, the one or more electromagnets are moveably arranged relative to the permanent magnets. Hereby, it is possible to passivate the permanent magnets during installation (or detachment) and afterwards move the one or more electromagnets. In an embodiment, the one or more permanent magnets are moveably arranged relative to the one or more electromagnets and/or housing. Hereby, it is possible to passivate the permanent magnets during installation (or detachment) and afterwards move the one or more permanent magnets relative to the electromagnets and/or the housing.

The magnetizable surface may be a ferromagnetic metal such as iron and ferritic and martensitic stainless steels.

In an embodiment, the unit is configured to be attached on the magnetizable surface of a stationary mast.

In an embodiment, the unit is configured to be attached on the magnetizable surface of a light mast.

In an embodiment, the unit is configured to be attached on the magnetizable surface of a road traffic sign.

In an embodiment, the unit is configured to be attached on the magnetizable surface of a street name sign.

In an embodiment, the unit is configured to be attached on the magnetizable surface of a house covering.

In an embodiment, the unit is configured to be attached on the magnetizable surface of a chimney.

In an embodiment, the unit comprises and is powered by an energy harvester.

In an embodiment, the energy harvester is configured to generate energy from sunlight.

In an embodiment, the energy harvester is configured to generate energy from wind.

In an embodiment, the energy harvester is configured to generate energy from vibration.

In an embodiment, the energy harvester is configured to generate energy from temperature difference.

In an embodiment, the energy harvester is a thermoelectric generator.

In an embodiment, the one or more permanent magnets are coated with a sticky material. By having a sticky coating, the surface of the permanent magnet(s) is sticky. Accordingly, displacement of the units after attachment can be avoided.

In an embodiment, the one or more permanent magnets are flexible and configured to attached to various type of masts having various diameters and/or cross-sectional area geometries.

Flexible magnets can be produced by a ferrite magnet material mixed with a flexible rubber binder which is then extruded or calendared to create any desired profile including tape and sheets.

In an embodiment, the unit comprises a flexible magnet extender comprising two permanent magnets connected by a flexible structure.

Hereby, it is possible to extend the unit.

In an embodiment, the flexible structure is made of a spring.

In an embodiment, the flexible structure is made of rubber.

In an embodiment, the flexible structure is made of plastics.

In an embodiment, the flexible magnet extender is configured to extend the distance between magnets.

In an embodiment, the communication module is configured to communicate wirelessly in a mesh network with other devices of the same type of the unit.

In an embodiment, the unit is bendable.

In an embodiment, the housing of the unit is bendable.

In an embodiment, the housing is a hermetically sealed container that is so tightly closed that no air can leave or enter it.

In an embodiment, the unit is bendable to such an extent that the unit is suitable for being formed to bear against bend around mast having a diameter of less than 50 cm.

In an embodiment, the unit is bendable to such an extent that the unit is suitable for being formed to bear against bend around mast having a diameter of less than 20 cm.

In an embodiment, the unit comprises one or more batteries.

In an embodiment, the one or more batteries have sufficient energy to power the unit for one year during normal use.

In an embodiment, the unit is suitable for being installed using a drone.

In an embodiment, the unit comprises a processing unit that is electrically connected to the communication unit and to the battery and to the one or more electromagnets.

In an embodiment, the unit comprises a control button accessible from the outside of the unit, wherein the control button is connected to a processing unit that is arranged and configured to power the one or more electromagnets when the control button is activated (e.g., pushed, rotated or pulled).

The system according to embodiments of the invention is a system comprising:
a unit according to embodiments of the invention and
a light mast having a light source, wherein the unit is mounted on the light mast, wherein the unit comprises an energy harvester that is arranged and configured to harvest energy from the light of the light mast. Hereby, it is possible to harvest energy to the unit in an easy manner.

Applying one or more electromagnets to passivate the one or more permanent magnets during installation of the unit provides an enlarged freedom to move the unit even when the permanent magnets are in contact with the magnetizable surface.

In an embodiment, the one or more electromagnets constitute a part of the unit. This means that the one or more electromagnets are integrated in the unit.

In an embodiment, the unit comprises two rows of permanent magnets on the rear side of the housing. This may be an advantage and allow the unit to be firmly attached to a magnetizable surface.

In an embodiment, the one or more permanent magnets of the unit are mounted on a metal plate on a rear side of the unit, so they can be arranged to fit the surface the must be installed on.

In an embodiment, the permanent magnets of the unit are flexible, so they can easier fit the surface the must be installed on.

In an embodiment, the unit is suitable for being installed using a stick, to allow for ease of installation. In an embodiment, the unit is configured to be installed using a flying drone, to allow for ease of installation.

In an embodiment, the permanent magnets are passivated (alias neutralized or inactivated) by electromagnets during installation, to avoid that the permanent magnets are used to attach the unit in an undesired position during installation. Each of the electromagnets can cover one or more of the permanent magnets.

In an embodiment, the electromagnets are open core design to make it is easier to position it during installation).

In an embodiment, the unit comprises and is configured to be mounted using flexible magnet extenders, to support ease of installation. The magnet extenders consist of two permanent magnets with a flexible element extending between the two permanent magnets. The flexible element can be made of e.g., rubber, plastics, or a spring.

In an embodiment, the unit comprises an energy harvester formed as a solar cell, configured to harvest energy from light. This light can come from e.g., the sun and/or artificial light. When the cell is mounted on a light mast or similar, the light might come from the light mast. A benefit of harvesting energy from the light from the light mast is that the cell can harvest more energy in dark periods such as night and winter.

In an embodiment, the unit comprises and is powered by a wind turbine which harvests energy from wind.

In an embodiment, the unit comprises and is powered by a kinetic energy harvester which harvests energy from vibration.

In an embodiment, the unit comprises and is powered by a thermoelectric generator which harvests energy thermal gradients. In an embodiment, the permanent magnets are coated with a material to make the surface sticky, to avoid that the cell is displaced after it is mounted; e.g., by wind or gravity. The coating material can be chosen from e.g., rubber, polymers with large surfaces, or micro grains of e.g., tin or silicon.

In an embodiment, the unit is flexible. Hereby, it is possible to allow the unit to be bent around e.g., a mast, for ease of installation.

The kit according to embodiments of the invention is a kit comprising a unit according to embodiments of the invention and an installation device comprising one or more electromagnets arranged in such a manner that the one or more electromagnets can be moved in a position, in which the one or more electromagnets can passivate the one or more permanent magnets when the unit is being mounted on the magnetizable surface.

The method according to embodiments of the invention is a method for attaching a wireless data communication unit to a magnetizable surface, the unit comprising housing having:
a communication module configured to communicate wirelessly,
one or more permanent magnets arranged in a manner that enables the unit to be mounted on the magnetizable surface by the one or more permanent magnets, wherein the unit is a self-contained unit formed as a closed housing that is not connected to external power, communication or antenna using cables or wires, wherein embodiments of the method comprise the step of applying one or more electromagnets arranged and configured to passivate the one or more permanent magnets during installation of the unit, wherein the one or more permanent magnets protrude from the housing.

Hereby, it is possible to provide an improved method that eases the mounting procedure. In an embodiment, the one or more electromagnets constitute a part of the unit. In an embodiment, the one or more electromagnets does not constitute a part of the unit.

In an embodiment, the one or more electromagnets are flexible.

In an embodiment, the housing comprises a plurality of permanent magnets protruding from a single surface of the housing, wherein the permanent magnets extend parallel to each other.

In an embodiment, the permanent magnets are spaced from each other.

In an embodiment, the permanent magnets have the same length.

### BRIEF DESCRIPTION

Some of the embodiments will be described in detail, with references to the following Figures, wherein like designations denote like members, wherein:

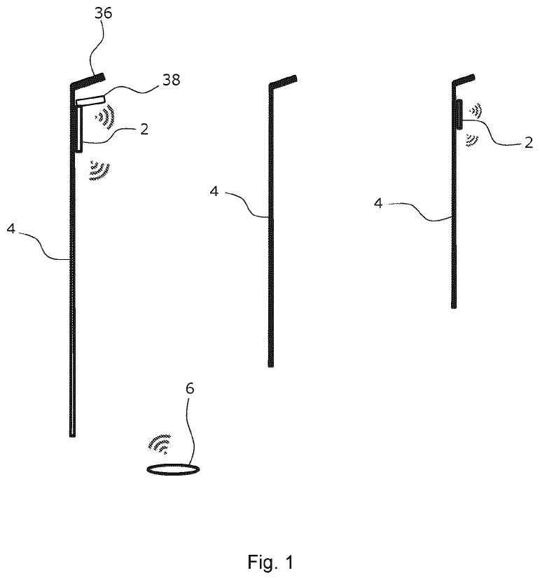

FIG. 1 shows a wireless communication setup according to embodiments of the invention;

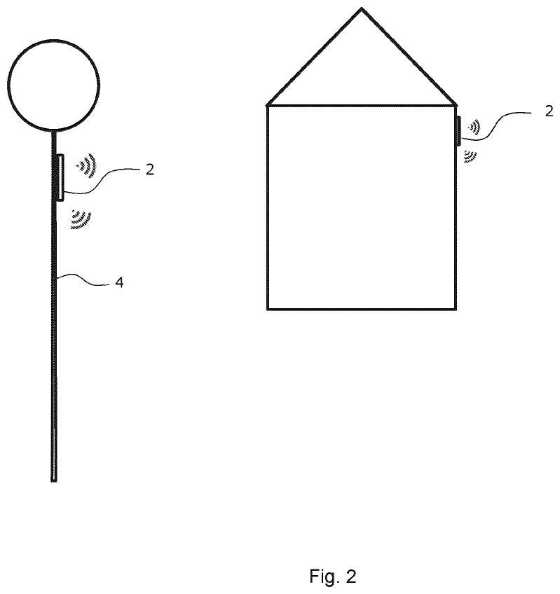

FIG. 2 shows a wireless communication setup according to embodiments of the invention;

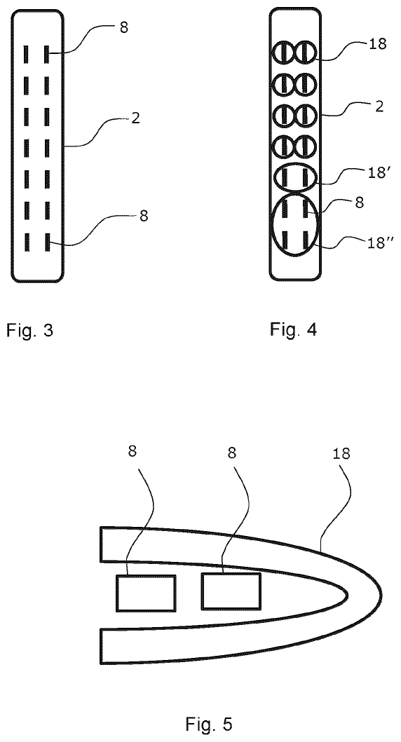

FIG. 3 shows a wireless communication unit according to embodiments of the invention;

FIG. 4 shows a wireless communication unit according to embodiments of the invention with permanent magnets on its rear side;

FIG. 5 shows an electromagnet of wireless communication unit according to embodiments of the invention;

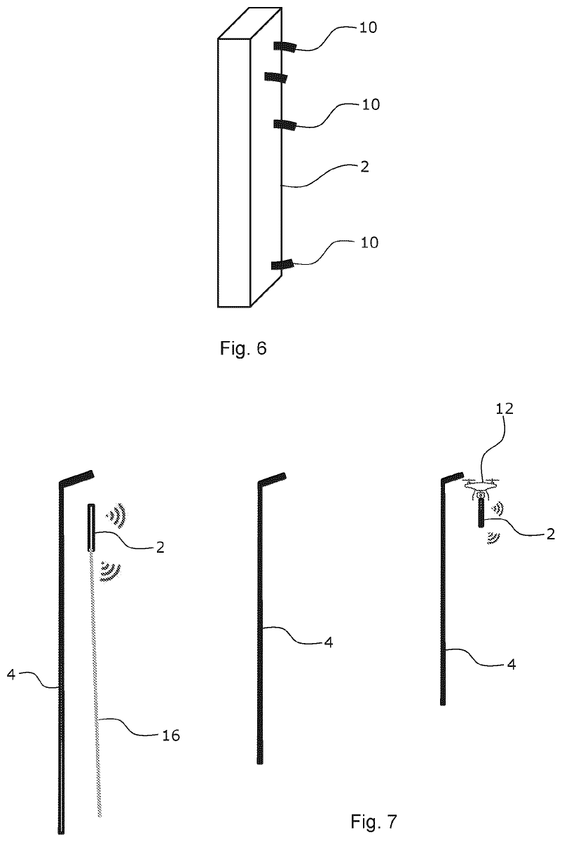

FIG. 6 shows a wireless communication unit according to embodiments of the invention;

FIG. 7 shows how wireless communication units according to embodiments of the invention are being attached to masts;

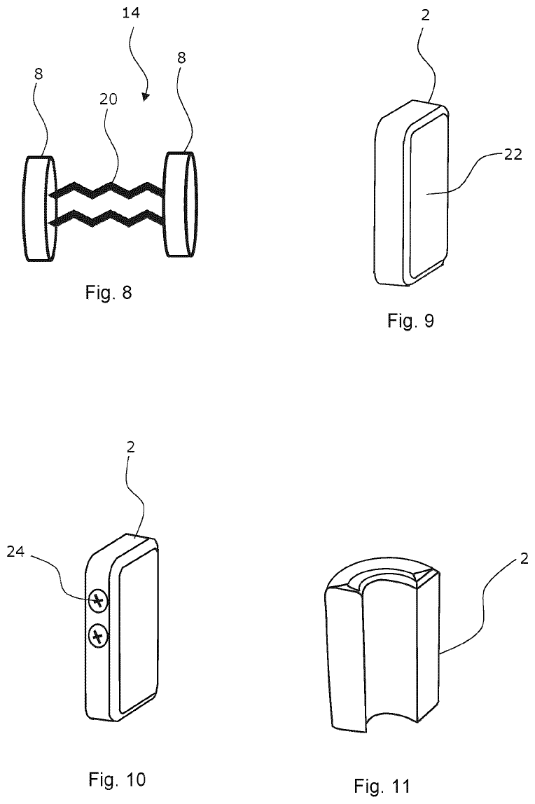

FIG. 8 shows a flexible magnet extender according to embodiments of the invention;

FIG. 9 shows a wireless communication unit according to embodiments of the invention;

FIG. 10 shows another wireless communication unit according to embodiments of the invention;

FIG. 11 shows a further wireless communication unit according to embodiments of the invention;

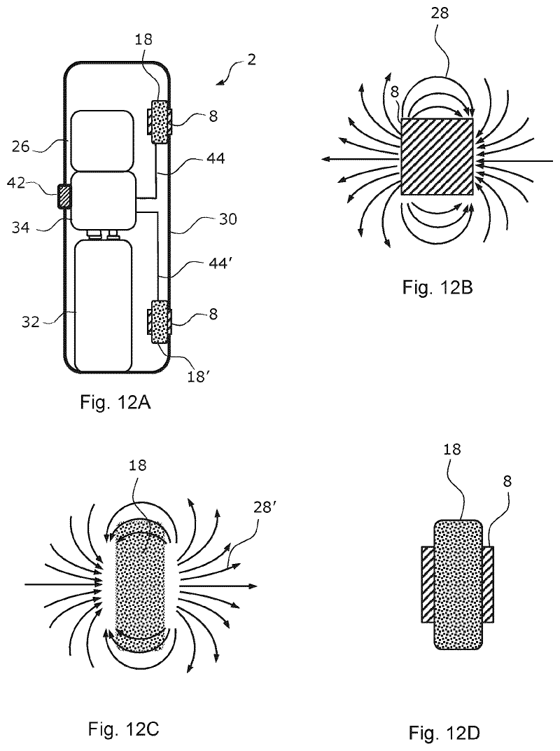

FIG. 12A shows a cross-sectional view of a wireless communication unit according to embodiments of the invention;

FIG. 12B shows the magnet field lines of a permanent magnet of the unit shown in FIG. 12A;

FIG. 12C shows the magnet field lines of an electromagnet of the unit shown in FIG. 12A;

FIG. 12D shows that the magnet field lines of the electromagnet and the magnet field lines of a permanent magnet cancel each other out due to the superposition principle;

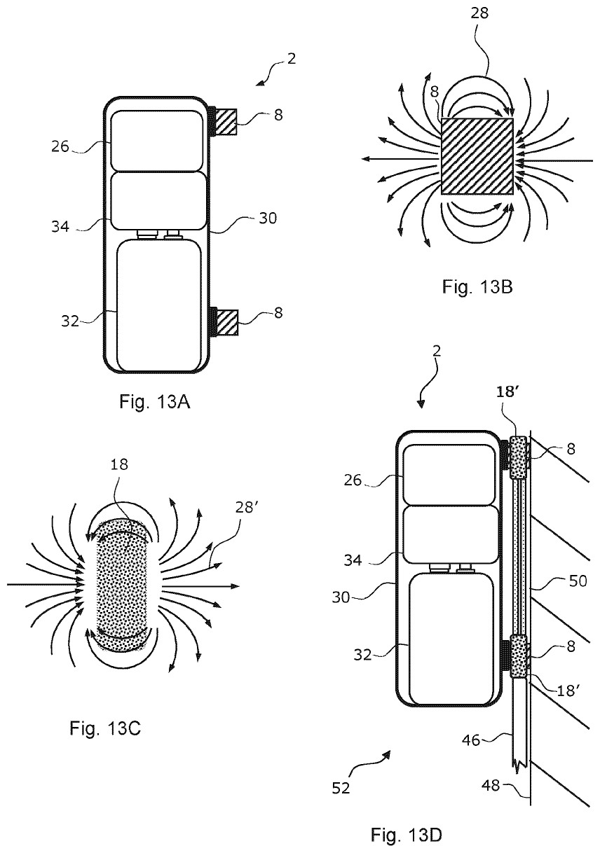

FIG. 13A shows a cross-sectional view of a wireless communication unit according to embodiments of the invention;

FIG. 13B shows the magnet field lines of a permanent magnet of the unit shown in FIG. 13A;

FIG. 13C shows the magnet field lines of an electromagnet of the installation device shown in FIG. 13D; and

FIG. 13D shows a kit according to embodiments of the invention.

### DETAILED DESCRIPTION

Referring now in detail to the drawings for the purpose of illustrating embodiments of the present invention, a wireless communication unit 2 of embodiments of the present invention is illustrated in FIG. 1. FIG. 1 illustrates a wireless communication setup according to embodiments of the invention. Two units 2 have been installed (attached to) in light masts 4, and a wireless sensor 6 has been installed underground. The units 2 can function as range extenders. The units 2 can be interconnected to form an independent network of range extenders or local area network. This network of units 2 may operate in a mesh network.

The leftmost unit 2 comprises an energy harvester 38 arranged to receive light emitted by the light source 36 of the light mast 4. Accordingly, the unit 2 is capable of harvesting energy from the light source 38.

FIG. 2 illustrates a wireless communication setup according to embodiments of the invention. A first unit 2 is attached to a road sign mast 4 while a second unit 2 is attached to the coverage of a house.

FIG. 3 illustrates a wireless communication unit according to embodiments of the invention. The unit 2 comprises a plurality of permanent magnets 8 arranged on the rear side of the unit 2. The permanent magnets 8 are arranged and configured for mounting the unit 2 to a magnetizable surface.

FIG. 4 illustrates a wireless communication unit 2 corresponding to the one shown in FIG. 4. A plurality of permanent magnets 8 are provided on the rear side of the unit 2. The unit 2 comprises several electromagnets 18, 18′, 18″ arranged to passivate the permanent magnets 8 during installation of the unit 2. The electromagnets 18, 18′, 18″ can also be used to passivate the permanent magnets 8 during deinstallation of the unit 2.

Each of the electromagnets 18, 18′, 18″ coves one or more of the permanent magnets 8. The first electromagnet 18 covers and is configured to passivate a single permanent magnet 8. The second electromagnet 18′ covers and is configured to passivate two permanent magnets 8 at the same time. The third electromagnet 18″ covers and is configured to passivate four permanent magnets 8 at the same time.

FIG. 5 illustrates a schematic view of an electromagnet 18 of wireless communication unit according to embodiments of the invention. The electromagnet 18 has an opening, that allows the electromagnet to be moved into a temporary position during installation and deinstallation.

FIG. 6 illustrates a wireless communication unit 2 according to embodiments of the invention. The unit 2 comprises several flexible magnets 8 arranged on and protruding from the housing of the unit. The flexible magnets 8 are arranged and configured to allow the unit 2 to be attached to a magnetizable surface.

FIG. 7 illustrates how wireless communication units 2 according to embodiments of the invention are being attached to light masts 4. A first unit 2 is being attached to a mast 4 by a stick 16, wherein the unit 2 is provided at the upper free end of the stick 16. A second unit 2 is being attached to another mast 4 by a flying drone 12.

FIG. 8 illustrates a flexible magnet extender 14 according to embodiments of the invention. The flexible magnet extender 14 comprises two magnets 8 with a flexible unit 20 extending in-between. The flexible unit 20 is made of a flexible material. The flexible material may be a spring, rubber, or plastics.

FIG. 9 illustrates a wireless communication unit 2 according to embodiments of the invention. The unit 2 comprises an integrated solar cell 22. The solar cell 22 is arranged and configured to power the unit 2.

FIG. 10 illustrates a wireless communication unit 2 according to embodiments of the invention. The unit 2 comprises an integrated wind turbine 24. The integrated wind turbine 24 is arranged and configured to power the unit 2. The unit 2 may comprise several integrated wind turbines 24.

FIG. 11 illustrates a wireless communication unit 2 according to embodiments of the invention. The unit is flexible to such an extent that the unit 2 can be bent around e.g., a mast 4, for ease of installation. FIG. 12A illustrates a cross-sectional view of a wireless communication unit 2 according to embodiments of the invention. The unit 2 comprises a housing 30. In an embodiment, the housing 30 is a hermetically sealed container that is so tightly closed that no air can leave or enter it.

The unit 2 comprises a battery 21 and a processing unit 34 that function as a control unit that is electrically connected to the battery 32. The unit 2 comprises a battery 21 and a communication unit 26 that may comprise an integrated antenna. The communication unit 26 is attached to the processing unit 34. A control button 42 is electrically connected to the processing unit 34. The control button 42 is accessible from the outside of the housing 30 so that a user easily can access the control button 42. The processing unit 34 is electrically connected to a first electromagnet 18 and a second electromagnet 18′ by wired connections 44, 44′. Accordingly, the control button 42 can activate the first electromagnet 18 and a second electromagnet 18′ and hereby generate a magnetic field corresponding to the one shown in FIG. 12C.

The first electromagnet 18 surrounds a portion of a first permanent magnet 8. Likewise, the second electromagnet 18′ surrounds a portion of a second permanent magnet 8′. The electromagnets 18, 18′ are arranged and configured to cancel out the magnet field of the permanent magnets 8. Accordingly, when the control button 42 is activated, the first electromagnet 18 and a second electromagnet 18′ generate magnetic fields that cancel out the magnet field of the permanent magnets 8.

FIG. 12B illustrates the magnet field lines 28 of a permanent magnet 8 of the unit 2 shown in FIG. 12A.

FIG. 12C illustrates the magnet field lines 28′ of an electromagnet 18 of the unit 2 shown in FIG. 12A. It can be seen that the magnet field lines 28′ of an electromagnet 18 cancel out the magnet field lines 28 of the permanent magnet 8 shown in FIG. 12B due to the superposition principle.

FIG. 12D illustrates that the magnet field lines of the electromagnet 18 and the magnet field lines of a permanent magnet 8 (shown in FIG. 12A) cancel each other out due to the superposition principle.

FIG. 13A illustrates a cross-sectional view of a wireless communication unit 2 according to embodiments of the invention. The unit 2 comprises a housing 30.

The unit 2 comprises a battery 21 and a processing unit 34 that function as a control unit that is electrically connected to the battery 32. The unit 2 comprises a battery 21 and a communication unit 26 that may comprise an integrated antenna. The communication unit 26 is attached to the processing unit 34. The unit 2 comprises a first permanent magnet 8 protruding from the housing 30. Likewise, the unit 2 comprises a second permanent magnet 8′ protruding from the housing 30. The permanent magnets 8 protrude from the housing 30 to such an extent that permanent magnets 8 can be passivated by one or more electromagnets 18, 18′ of the installation device 46 shown in FIG. 13D when the unit 2 is being mounted on the magnetizable surface 48.

FIG. 13B illustrates the magnet field lines 28 of a permanent magnet 8 of the unit 2 shown in FIG. 13A.

FIG. 13C illustrates the magnet field lines 28′ of an electromagnet 18 of the installation device 46 shown in FIG. 13D. The magnet field lines 28′ of the electromagnet 18 cancel out the magnet field lines 28 of the permanent magnet 8 shown in FIG. 13B due to the superposition principle.

FIG. 13D illustrates a kit 52 according to embodiments of the invention. The kit 52 comprising a unit 2 corresponding to the one shown in and explained with reference to FIG. 13A and an installation device 46 comprising several more electromagnets 18, 18′ arranged in such a manner that each of the electromagnets 18, 18′ can be moved in a position, in which the electromagnets 18, 18′ can passivate the permanent magnets 8 of the unit 2 when the unit 2 is being mounted on the magnetizable surface 48.

The electromagnets 18, 18′ are arranged and configured to cancel out the magnet field of the permanent magnets 8. Accordingly, when the unit 2 and the installation device 46 are arranged as shown in FIG. 13D, the first electromagnet 18 and a second electromagnet 18′ generate magnetic fields that cancel out the magnet field of the permanent magnets 8. Accordingly, the unit 2 can be moved into the desired position and be attach to the magnetizable surface 48 (by deactivating or moving the electromagnets 18, 18′).

It can be seen that the electromagnets 18, 18′ enclose part of the permanent magnets 8 while a gap 50 is provided between the installation device 46 and the magnetizable surface 48. This is achieved by applying an installation device 46 having a width that is smaller than the width with which the permanent magnets 8 protrude from the housing 30.

The installation device 46 may be integrated in the stick shown in and explained with reference to FIG. 7.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements. The mention of a “unit” or a “module” does not preclude the use of more than one unit or module.

### LIST OF REFERENCE NUMERALS

2 Wireless cell
4 Mast where the wireless cell can be installed
6 Wireless sensor
8 Permanent magnet
10 Flexible permanent magnet
12 Drone for installation of the cell
14 Flexible magnet extender
16 Installation stick
18, 18′, 18″ Electromagnet
20 Flexible structure
22 Solar cell (solar panel)
24 Wind turbine
26 Communication module
28, 28′ Magnetic
30 Housing
32 Battery
34 Processing unit
36 Light source
38 Energy harvester
40 Sticky material
42 Control button
44, 44′ Wired connection
46 Installation device
48 Magnetizable surface
50 Gap
52 Kit

1. A wireless data communication unit comprising:
a communication module configured to communicate wirelessly,
one or more permanent magnets arranged in a manner that enables the unit to be mounted on a magnetizable surface by the one or more permanent magnets, wherein the unit is a self-contained unit formed as a closed housing that is not connected to external power, communication or antenna using cables or wires, wherein the one or more permanent magnets protrude from the housing to such an extent that the one or more permanent magnets can be passivated by one or more electromagnets arranged and configured to passivate the one or more permanent magnets when the unit is being mounted on the magnetizable surface,

2. The unit according to claim 1, wherein the unit comprises and is powered by an energy harvester.

3. The unit according to claim 1, wherein the one or more permanent magnets are coated with a sticky material.

4. The unit according to claim 1, wherein the one or more permanent magnets are flexible and configured to attached to various type of masts having various diameters and/or cross-sectional area geometries.

5. The unit according to claim 1, wherein the unit comprises a flexible magnet extender comprising two permanent magnets connected by a flexible structure

6. The unit according to claim 1, wherein the unit is bendable.

7. The unit according to claim 6, wherein the housing is bendable.

8. The unit according to claim 1, wherein the housing is a hermetically sealed container that is so tightly closed that no air can leave or enter it.

9. The unit according to claim 1, wherein the unit comprises one or more batteries.

10. A system comprising:
a unit according to claim 1 and
a light mast having a light source, wherein the unit is mounted on the light mast, wherein the unit comprises an energy harvester that is arranged and configured to harvest energy from the light of the light mast.

11. A kit comprising a unit according to claim 1 and an installation device comprising one or more electromagnets arranged in such a manner that the one or more electromagnets can be moved in a position, in which the one or more electromagnets can passivate the one or more permanent magnets when the unit is being mounted on the magnetizable surface.

12. A method for attaching a wireless data communication unit a magnetizable surface, the unit comprising housing having:
a communication module configured to communicate wirelessly; and
one or more permanent magnets arranged in a manner that enables the unit to be mounted on the magnetizable surface by of the one or more permanent magnets, wherein the unit is a self-contained unit formed as a closed housing that is not connected to external power, communication or antenna using cables or wires, wherein the method comprises the step of applying one or more electromagnets arranged and configured to passivate the one or more permanent magnets during installation of the unit, wherein the one or more permanent magnets protrude from the housing.

13. The method according to claim 12, wherein the one or more electromagnets constitute a part of the unit.

14. The method according to claim 12, wherein the one or more electromagnets does not constitute a part of the unit.

15. The method according to claim 12, wherein the one or more electromagnets are flexible.

16. The method according to claim 12, wherein the housing comprises a plurality of permanent magnets protruding from a single surface of the housing, wherein the permanent magnets extend parallel to each other.
